(19) United States
(12) Patent Application Publication
(10) Pub. No.: US 2025/0366050 A1
(43) Pub. Date: Nov. 27, 2025

(54) DEVICE AND METHOD TO REDUCE MG TO SD CAPACITANCE BY AN AIR GAP BETWEEN MG AND SD

(71) Applicant: Taiwan Semiconductor Manufacturing Co., Ltd., Hsinchu (TW)

(72) Inventors: Chun Yi CHOU, Hsinchu (TW); Guan-Lin CHEN, Hsinchu (TW); Shi Ning JU, Hsinchu (TW); Kuo-Cheng CHIANG, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/292,129

(22) Filed: Aug. 6, 2025

Related U.S. Application Data
(63) Continuation of application No. 18/410,852, filed on Jan. 11, 2024.
(60) Provisional application No. 63/578,413, filed on Aug. 24, 2023.

(51) Int. Cl. H10D 30/67; H10D 62/10; H10D 62/13; H10D 64/01; H10D 84/01; H10D 84/03; H10D 84/83

(52) U.S. Cl. CPC H10D 30/6735; H10D 30/6757; H10D 62/118; H10D 62/151; H10D 64/017; H10D 64/018; H10D 84/0128; H10D 84/013; H10D 84/0135; H10D 84/038; H10D 84/83

(57) ABSTRACT

A device includes a transistor. The transistor includes a plurality of stacked channels, a source/drain region coupled to the stacked channels, and a gate metal wrapped around the stacked channels. The transistor includes a plurality of inner spacers, each inner spacer being positioned laterally between the gate metal and the source/drain region and including a gap and an inner spacer liner layer between the gate metal and the source/drain region.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1Z and FIG. 2 are perspective and side-sectional views of an integrated circuit at various stages of processing, in accordance with some embodiments.

FIGS. 3A and 3B are perspective and side-sectional views of an integrated circuit, in accordance with some embodiments.

FIG. 4 is a side-sectional view of an integrated circuit, in accordance with some embodiments.

FIGS. 5A-5D are side-sectional views of an integrated circuit at various stages of processing, in accordance with some embodiments.

FIG. 6 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure reduce the capacitance between the source/drain regions and gate metals of a nanostructure transistor. The nanostructure transistor includes a plurality of channel regions extending between adjacent source/drain regions. The gate metal surrounds a portion of the channel regions. Inner spacers are formed between the source/drain regions and gate metal to electrically isolate the source/drain regions from the gate metal. Embodiments of the present disclosure form the inner spacers with a thin inner spacer liner layer between the gate metal and the source/drain regions. The inner spacers also include a gap or void between the inner spacer liner layer and the source/drain regions. The gaps have a very small dielectric constant. This results in a very low gate to source/drain capacitance. The low gate to source/drain capacitance results in improved performance of the transistor and improve performance of circuits implementing the transistor. This results in improved wafer yields and better functioning electronic devices.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

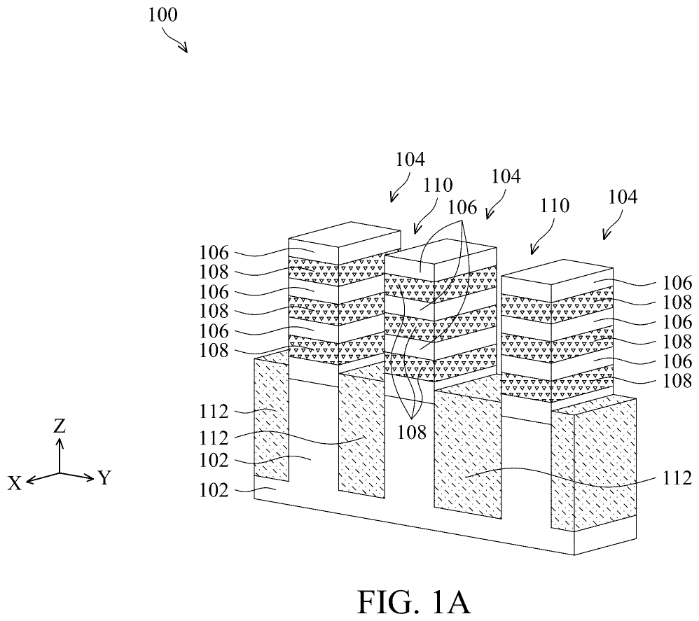

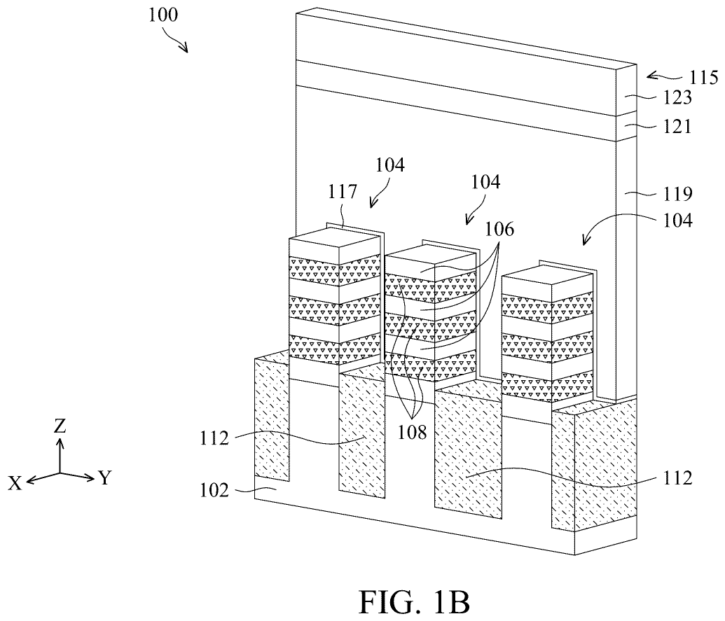

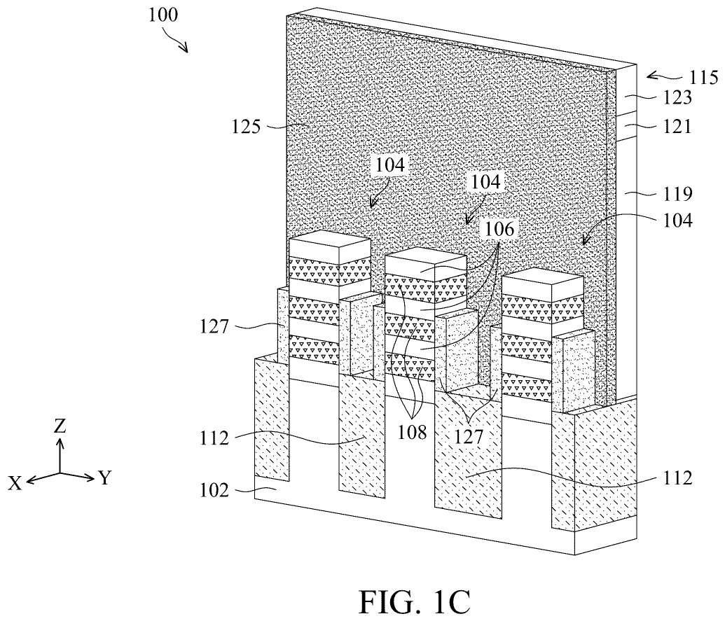

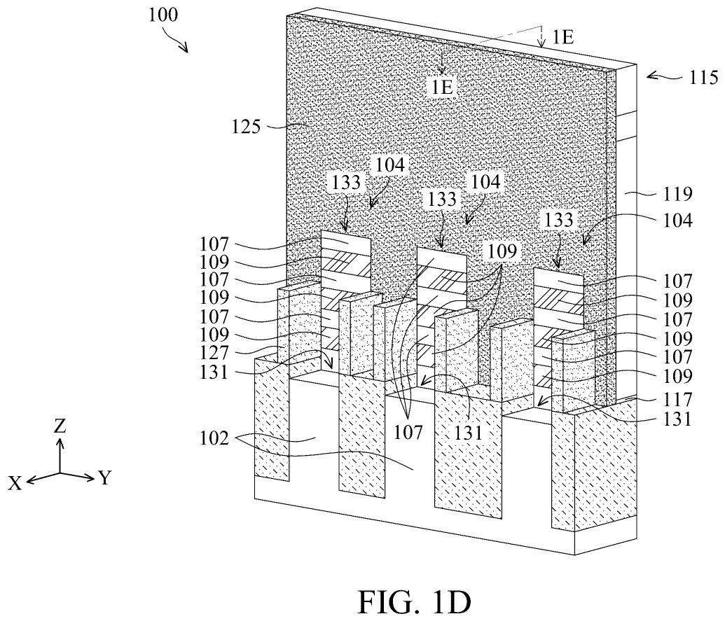

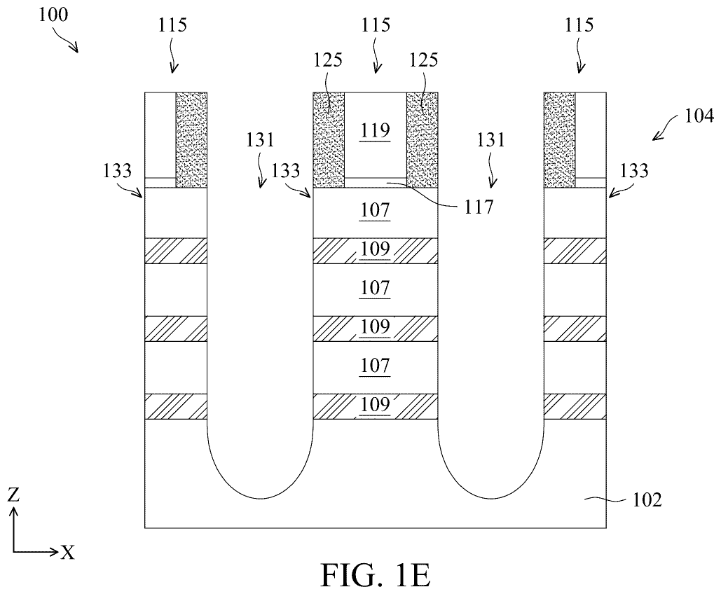

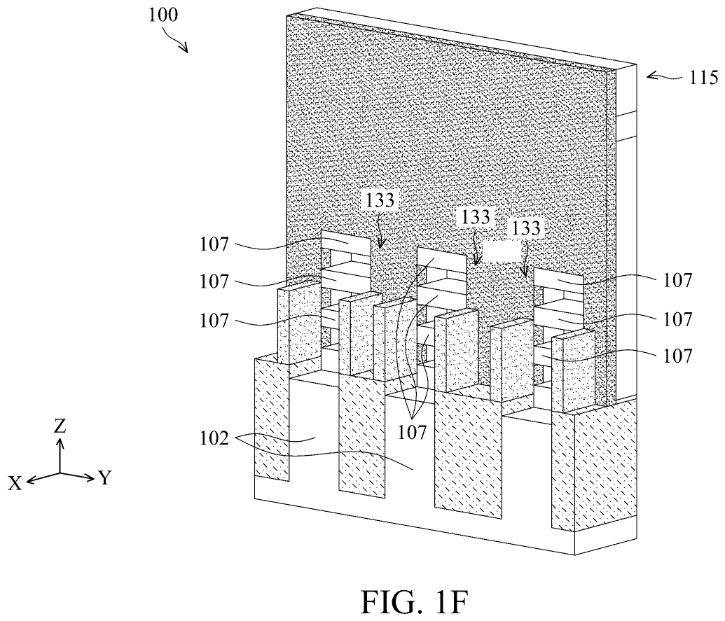

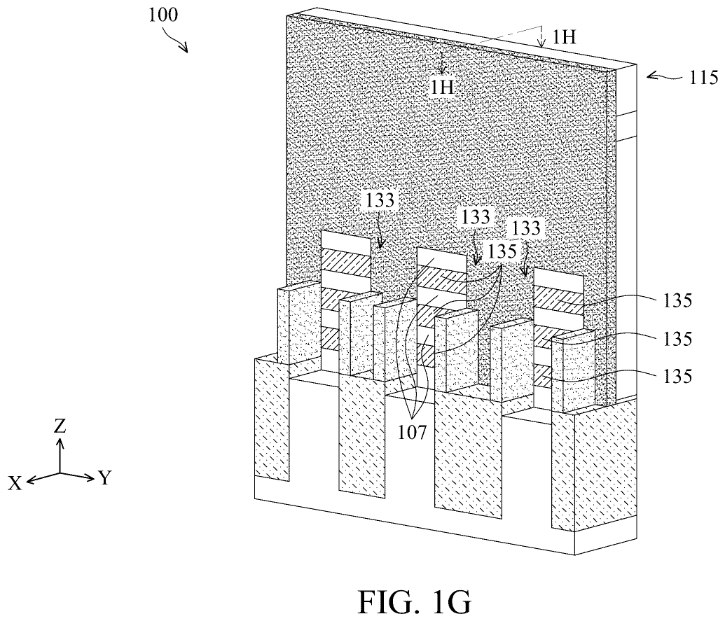

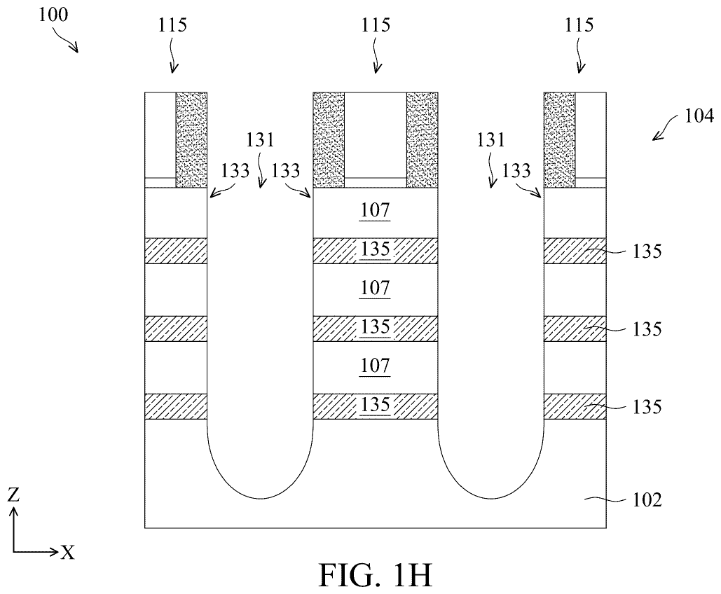

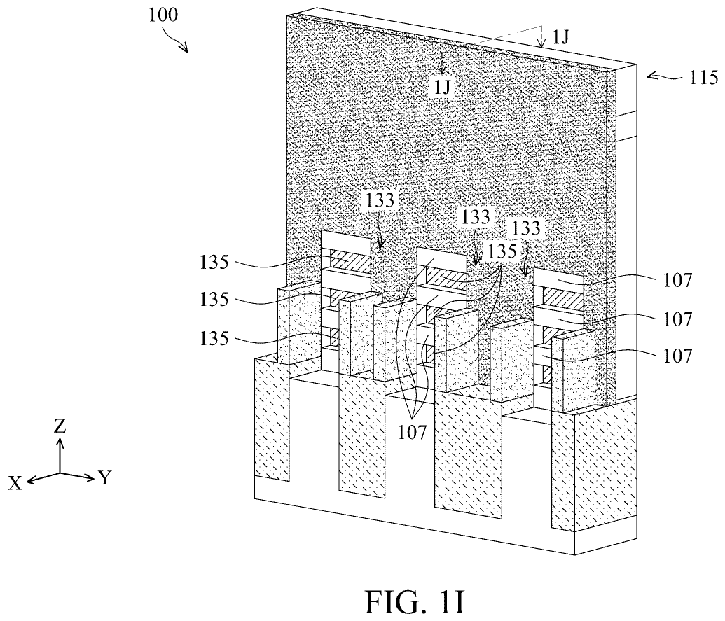

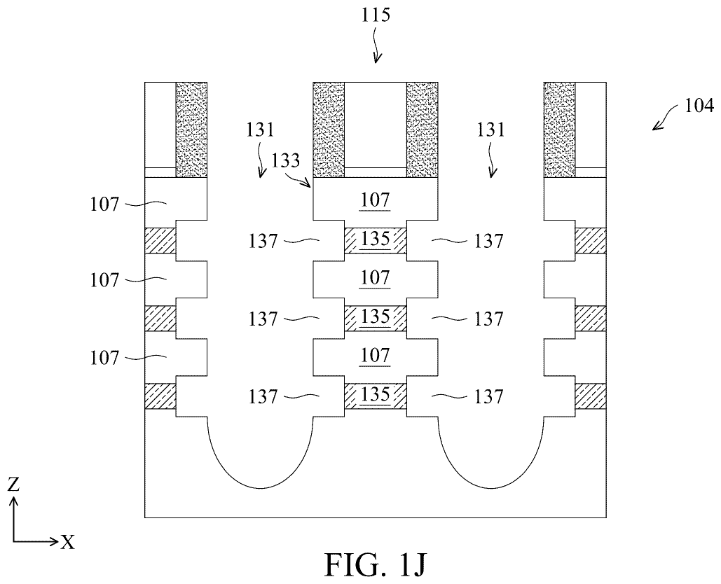

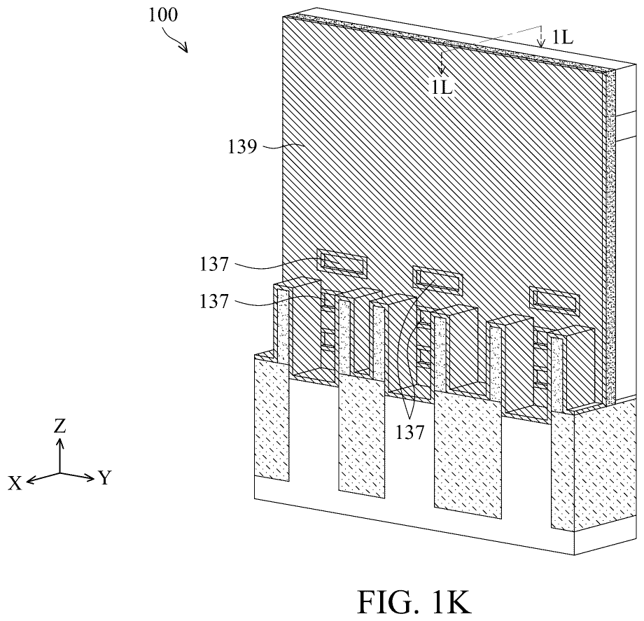

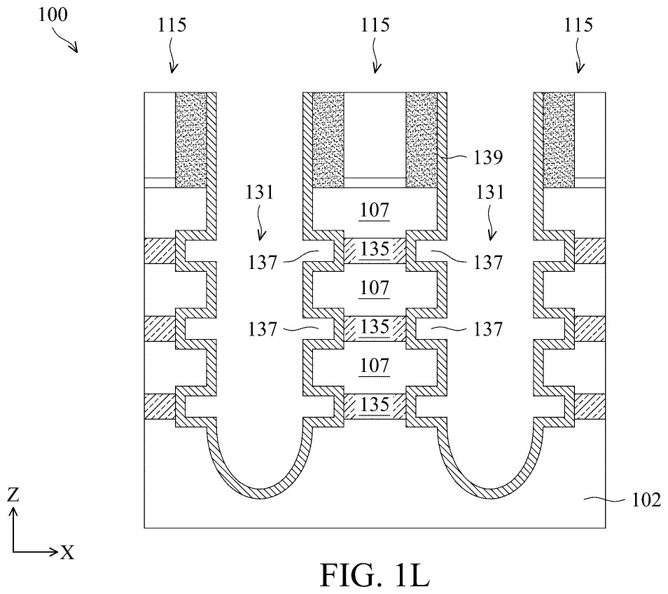

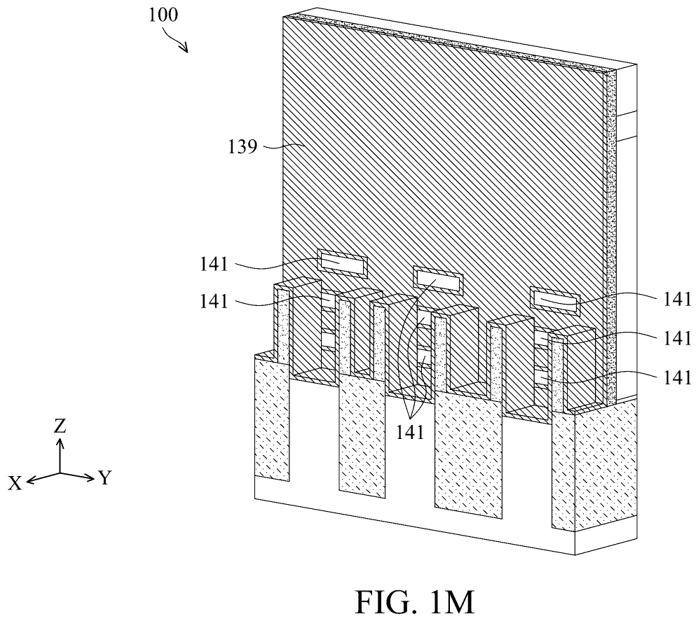

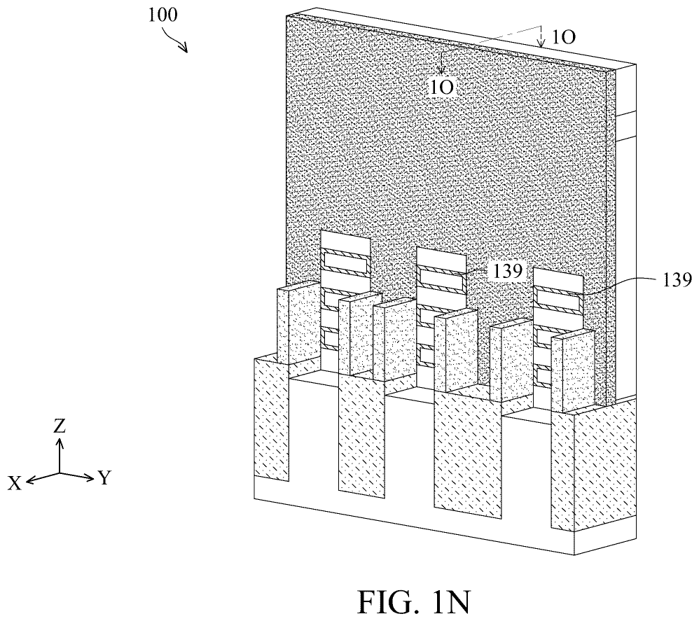

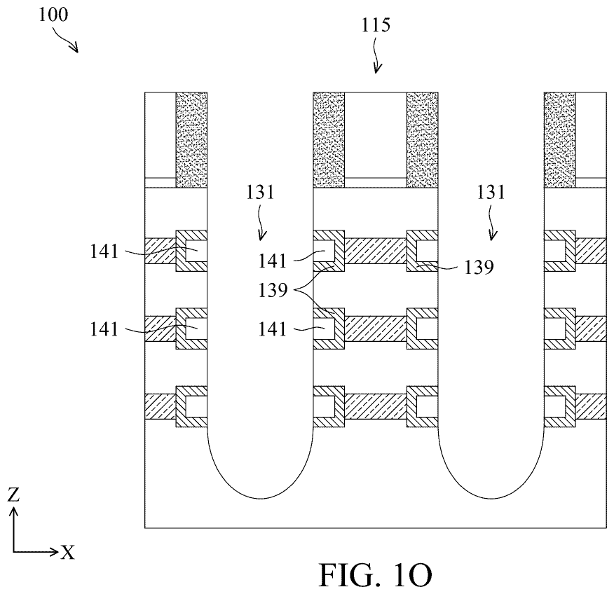

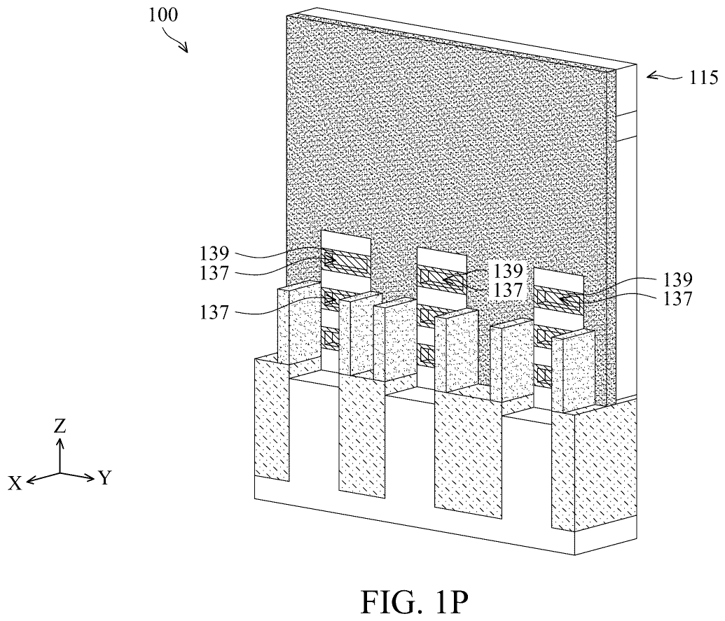

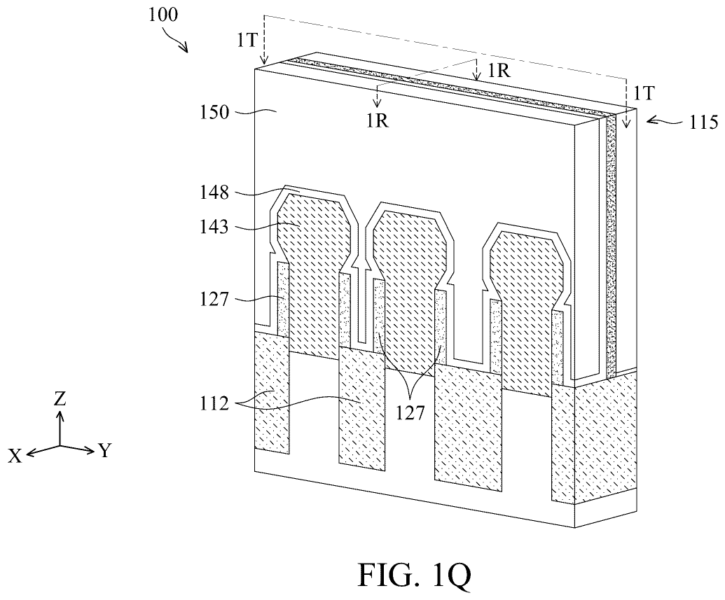

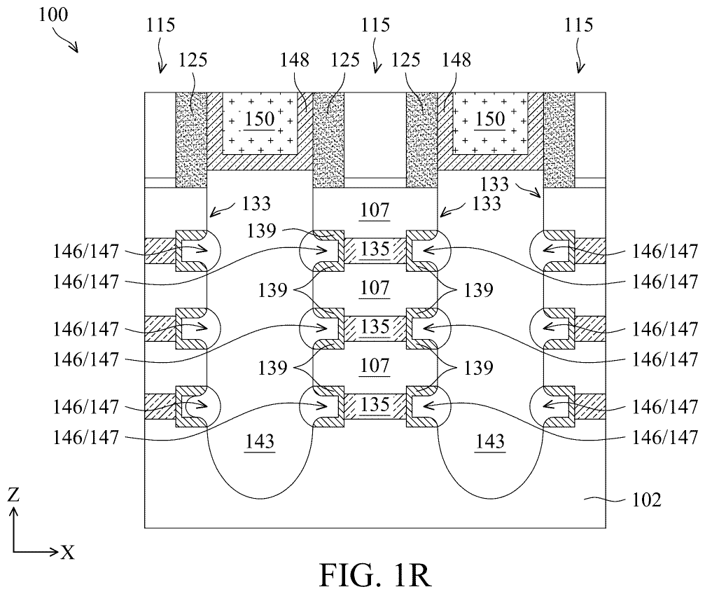

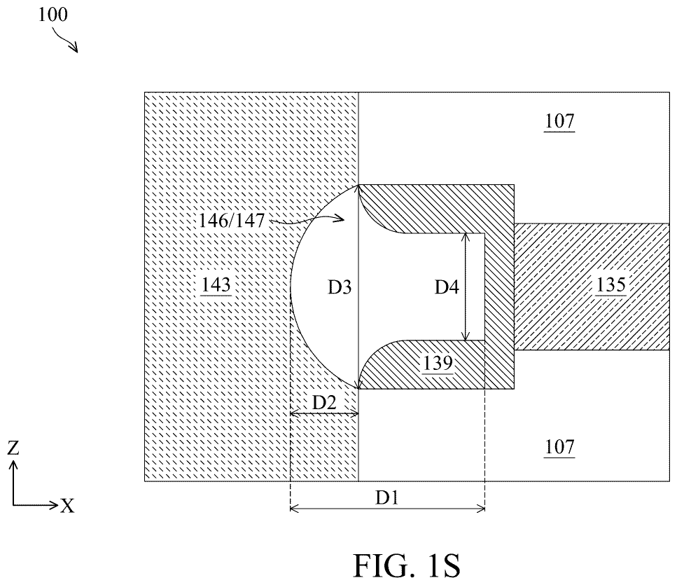

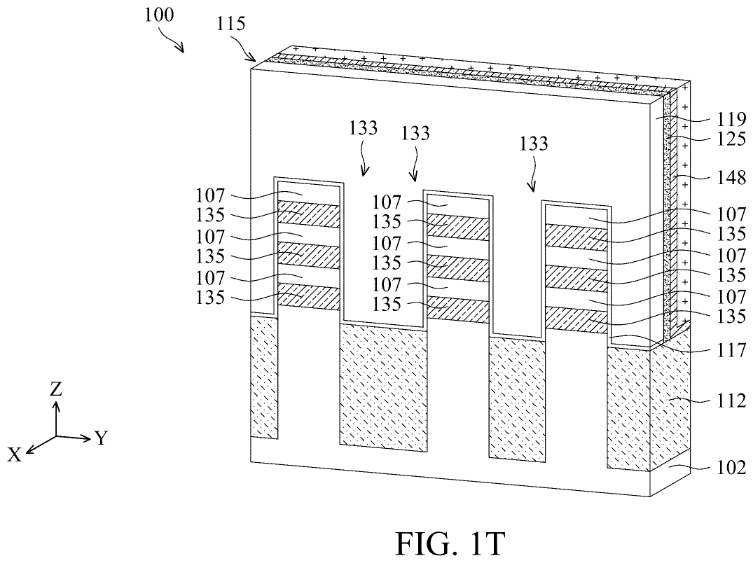

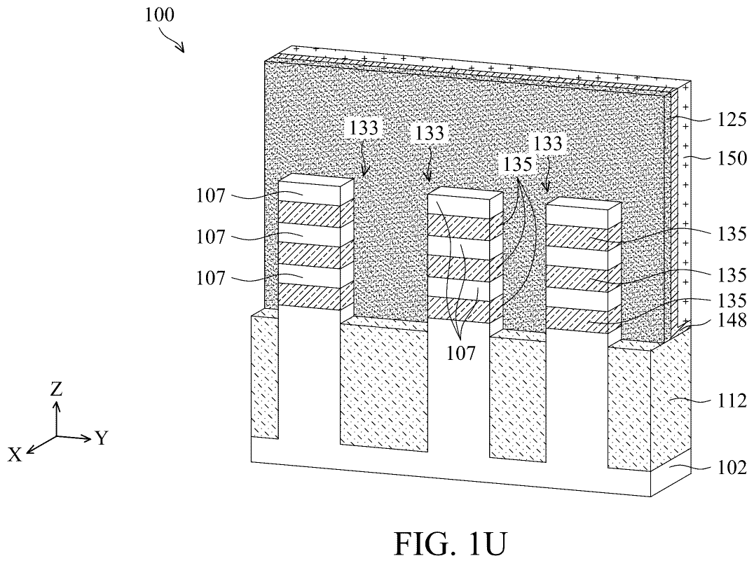

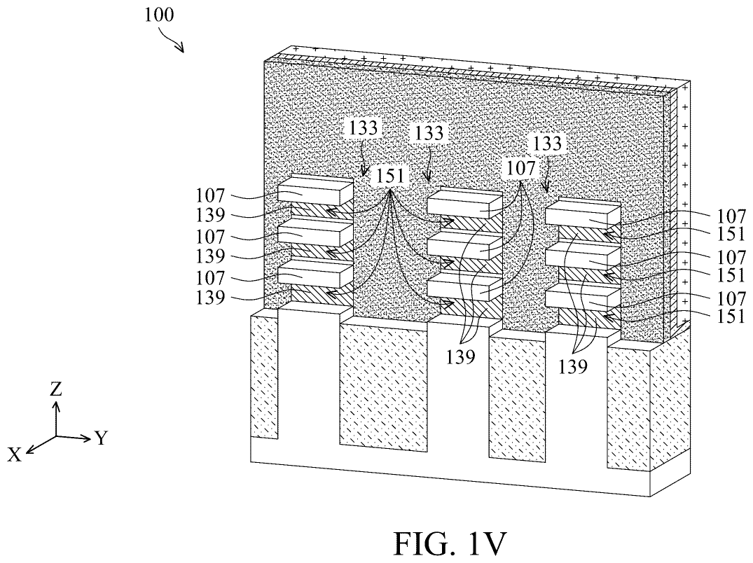

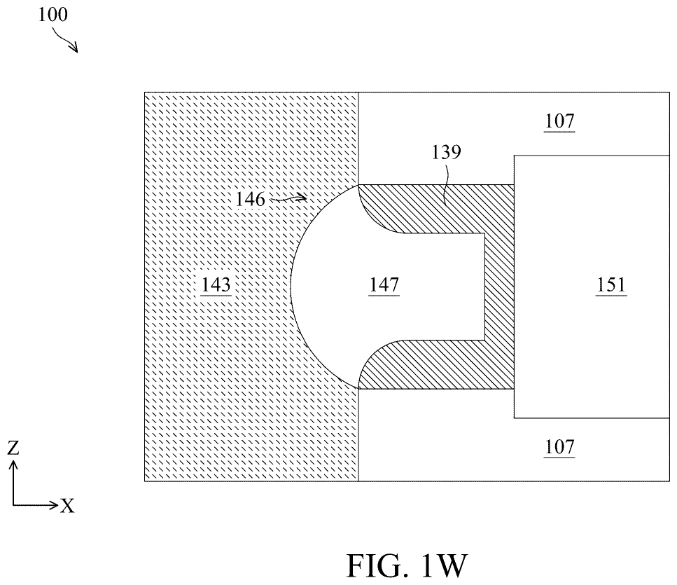

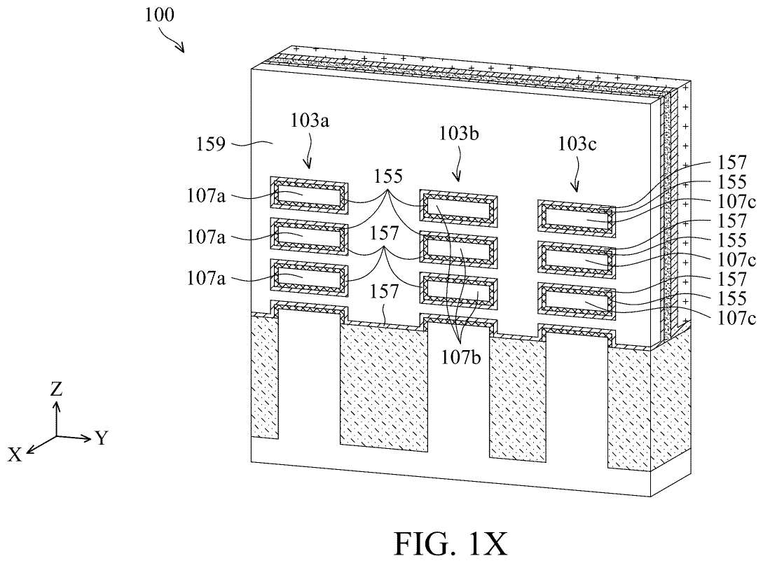

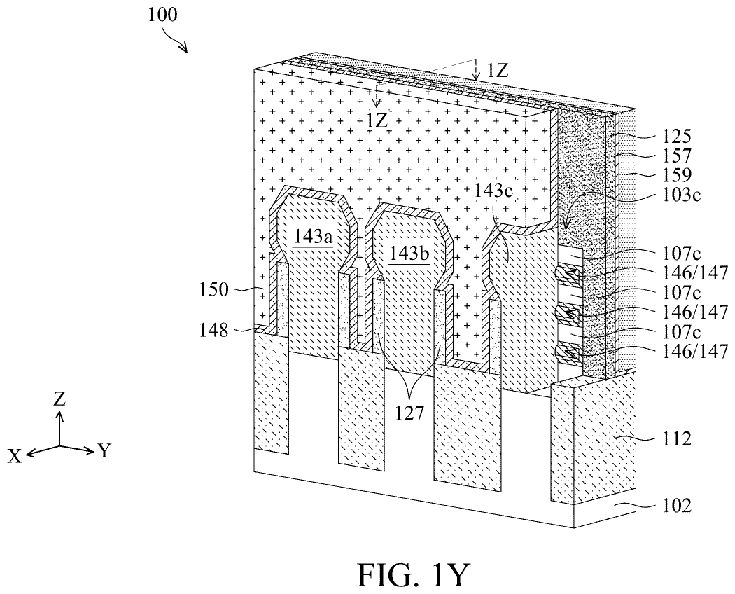

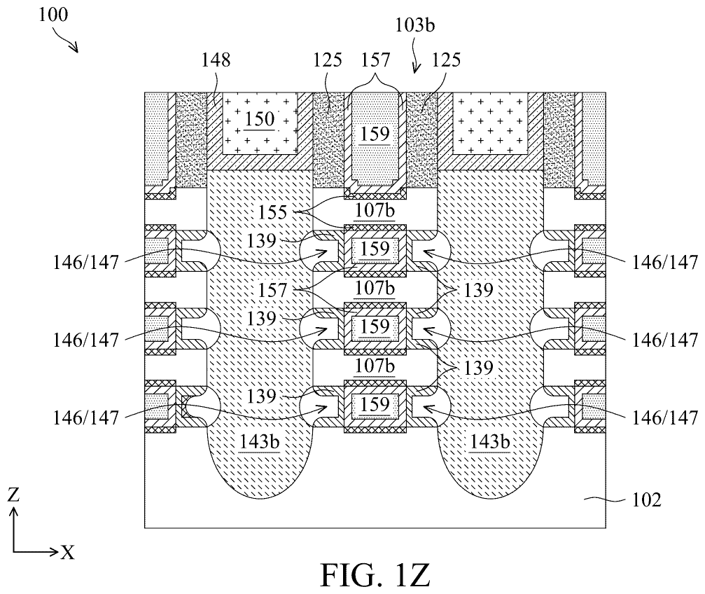

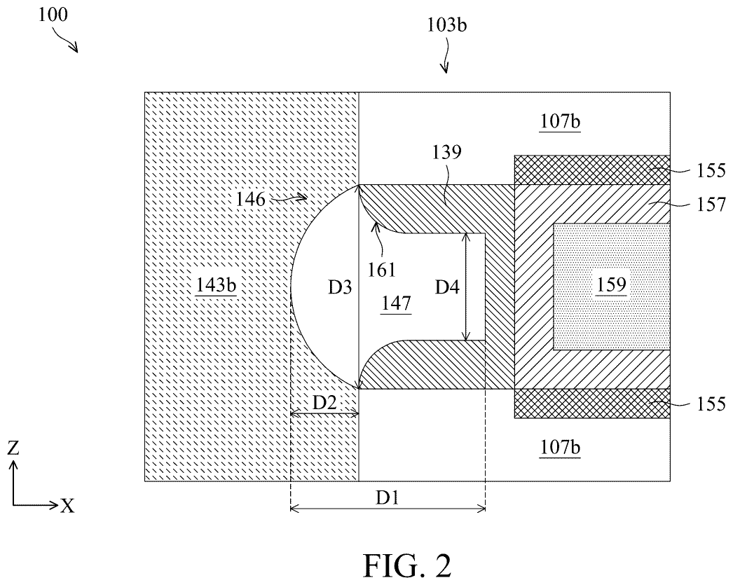

FIGS. 1A-Z and FIG. 2 are perspective and cross-sectional views of an integrated circuit 100 at various stages of processing, in accordance with some embodiments. The fabrication process results in a plurality of semiconductor nanostructure transistors, as will be described in further detail below.

FIG. 1A is a perspective view of the integrated circuit 100 at an intermediate state of processing, in accordance with some embodiments. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a plurality of semiconductor fins 104 extending from the substrate 102. Each semiconductor fin 104 includes a plurality of semiconductor layers 106 and sacrificial semiconductor layers 108 alternating with each other. As will be set forth in further detail below, the semiconductor layers 106 will be patterned to form semiconductor nanostructures of a plurality of transistors. As set forth in more detail below, the sacrificial semiconductor layers 108 will eventually be entirely removed and are utilized to enable forming gate metals and other structures around the semiconductor nanostructures. The semiconductor fins 104 extend in the X direction much further than is apparent in the view of FIG. 1A. Each semiconductor fin 104 will be patterned to form the source/drain trenches, thereby isolating individual stacks of channels and the nanostructures. Each individual stack will be utilized to form a transistor.

In some embodiments, the semiconductor layers 106 may be formed of a first semiconductor material suitable for n-type semiconductor nanostructure transistors, such as silicon, silicon carbide, or the like, and the sacrificial semiconductor layers 108 may be formed of a second semiconductor material suitable for p-type semiconductor nanostructure transistors, such as silicon germanium or the like. Each of the layers of the multi-layer stack 104 may be epitaxially grown using a process such as chemical vapor deposition (CVD), atomic layer deposition (ALD), vapor phase epitaxy (VPE), molecular beam epitaxy (MBE), or the like.

Three layers of each of the semiconductor layers 106 and the sacrificial semiconductor layers 108 are illustrated. In some embodiments, the multi-layer stack 104 may include one or two each or four or more each of the semiconductor layers 106 and the sacrificial semiconductor layers 108. Although the multi-layer stack 104 is illustrated as including a sacrificial semiconductor layer 108 as the bottommost layer of the multi-layer stack 104, in some embodiments, the bottommost layer of the multi-layer stack 104 may be a semiconductor layer 106.

Due to high etch selectivity between the materials of the semiconductor layers 106 and the sacrificial semiconductor layers 108, the sacrificial semiconductor layers 108 of the second semiconductor material may be removed without significantly removing the semiconductor layers 106 of the first semiconductor material, thereby allowing the semiconductor layers 106 to be released to form channel regions of semiconductor nanostructure transistors.

Initially, the semiconductor layers 106 and the sacrificial semiconductor layers 108 may be in a single stack without defined fins 104. An etching process has been performed in conjunction with a photolithography mask to define the fins 104 from the initial single stack. The etching process can include an anisotropic etching process that etches in the downward direction. The etching process defines fins 104 by forming trenches 110 through the sacrificial semiconductor layers 108, the semiconductor layers 106, and the substrate 102.

After formation of the trenches 110, trench isolation regions 112, which may be shallow trench isolation (STI) regions, have been formed in the trenches 110. The trench isolation regions 112 may be formed by depositing a dielectric material. In some embodiments, the dielectric material is formed over the substrate 102, the fins 104, and between adjacent fins 104. The dielectric material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 102 and the fins 104.

An etch-back process has been performed to reduce the top surface of the trench isolation regions 112 to a level below the lowest sacrificial semiconductor layer 108. The etching process can include a wet etch, dry etch, a timed etch, or other types of etching processes that can recess the height of the shallow trench isolation regions 112. The result is that the sidewalls of the semiconductor layers 106 and sacrificial semiconductor layers 108 of the fins 104 are exposed.

Though not shown in FIG. 1A, appropriate wells (not separately illustrated) may also be formed in the fins 104, the channels 107, and/or the trench isolation regions 112. Using masks, an n-type impurity implant may be performed in p-type regions of the substrate 102, and a p-type impurity implant may be performed in n-type regions of the substrate 102. Example n-type impurities may include phosphorus, arsenic, antimony, or the like. Example p-type impurities may include boron, boron fluoride, indium, or the like. An annealing may be performed after the implants to repair implant damage and to activate the p-type and/or n-type impurities. In some embodiments, in situ doping during epitaxial growth of the fins 104 and the channels 107 may obviate separate implantations, although in situ and implantation doping may be used together.

In FIG. 1B, sacrificial gate structures 115 have been formed over the fins 104, the trench isolation regions 112 and the channels 107, in accordance with some embodiments. Due to the limited nature of the view of FIG. 1B in the X-direction, only a single sacrificial gate structure 115 is shown in FIG. 1B. In practice, many other sacrificial gate structures 115 may be formed substantially parallel to and concurrently with the sacrificial gate structure 115 shown in FIG. 1B.

In FIG. 1B, a sacrificial gate dielectric layer 117 has been formed prior to forming the sacrificial gate structures 115. The gate dielectric layer 117 can include a SiO or other suitable dielectric materials. In some embodiments, the gate dielectric layer 117 has a low K dielectric material. The gate dielectric layer 117 can be deposited by CVD, ALD, or PVD.

The sacrificial gate structure 115 includes a sacrificial gate layer 119 on the sacrificial gate dielectric layer 117. The sacrificial gate layer can include materials that have a high etch selectivity with respect to the trench isolation regions 112. The sacrificial gate layer 119 may be a conductive, semiconductive, or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 119 may be deposited by physical vapor deposition (PVD), CVD, sputter deposition, or other techniques for depositing the selected material.

The sacrificial gate structure 115 includes a dielectric layer 121 on the sacrificial gate layer 119 and a dielectric layer 123 on the dielectric layer 121. The dielectric layers 121 and 123 may correspond to first and second mask layers. The dielectric layer 121 can include silicon nitride, silicon oxynitride, or other suitable dielectric materials. The dielectric layer 121 can include silicon nitride, silicon oxynitride or other suitable dielectric materials. The dielectric layers 121 and 123 are different materials from each other and can be deposited using CVD, ALD, PVD, or other suitable deposition processes. Other materials and deposition processes can be utilized for the dielectric layers 121 and 123 without departing from the scope of the present disclosure.

After deposition of the layers 117, 119, 121, and 123, the dielectric layers 121 and 123 may be patterned to act as a mask layers. An etching process may then be performed in the presence of the patterned dielectric layers in order to etch exposed regions of the sacrificial gate layer 119 and the sacrificial gate dielectric layer 117. This results in the structure shown in FIG. 1B.

In FIG. 1C, following formation of the sacrificial gate structure 115, one or more gate spacer layers 125 have been formed covering the sacrificial gate structure 115, the fins 104, and the trench isolation regions 112, in accordance with some embodiments. The gate spacer layer 125 can be formed by PVD, CVD, ALD, or other suitable deposition processes. Following formation of the gate spacer layer 125, horizontal portions (e.g., in the X-Y plane) of the gate spacer layer 125 may be removed, thereby exposing upper surfaces of the fins 104 and the trench isolation regions 112. The gate spacer layers 125 can include one or more of SiO, SiN, SiON, SiCN, SiOCN, SiOC, or other suitable dielectric materials.

In FIG. 1D, one or more etching operations have been performed to recess the fins 104 exposed through the gate spacer layer 125, in accordance with some embodiments. This etching process results in the formation of source/drain trenches 131 in the fins 104. The nature of the source/drain trenches 131 is more readily apparent in the cross-sectional view of FIG. 1E, taken along cut lines 1E in FIG. 1D.

FIG. 1E shows a single fin 104 extending in the X direction, in accordance with some embodiments. The etching process that forms the source/drain trenches 131 in the fin 104 also results in the singulation of individual stacks 133. Each stack includes a plurality of channels 107 and sacrificial semiconductor nanostructures 109. The channels 107 are formed from the semiconductor layers 106. The sacrificial semiconductor nanostructures 109 are formed from the sacrificial semiconductor layers 108. In the example of FIG. 1E, each stack 133 includes three stacked channels 107 and three sacrificial semiconductor nanostructures 109. The stacked channels 107 of each stack 133 of the channel regions of a transistor. Accordingly, an individual transistor will be formed in conjunction with each stack 133.

In the view of FIG. 1D, the source/drain trenches 131 appear to have a flat bottom in the substrate 102. However, in practice, the bottom of the source/drain trenches 131 may be rounded as shown in FIG. 1E.

FIG. 1E also illustrates a plurality of sacrificial gate structures 115 each crossing the fin 104 in the Y direction. The tops of the sacrificial gate structures 115 are not shown in FIG. 1E.

The etching processes to form the source/drain trenches 131 can include reactive ion etching (RIE), neutral beam etching (NBE), atomic layer etching (ALE), or the like. In practice, a large number of trenches 131 may be formed through fins 104 between large numbers of sacrificial gate structures 115.

In some embodiments, at the stage of processing of FIG. 1E, dielectric support elements 127 remain on the trench isolation regions 112. The dielectric support elements 127 are remnants of the gate spacer layers 125. The dielectric support elements 127 may be utilized to direct or confine the growth of source/drain regions.

In FIG. 1F, the sacrificial semiconductor nanostructures 109 have been removed via one or more etching processes, in accordance with some embodiments. Because the material of the sacrificial semiconductor nanostructures 109 is selectively etchable with respect to the material of the stacked channels 107, the sacrificial semiconductor nanostructures 109 can be removed without substantially etching the channels 107. The result is that there are gaps between adjacent stacked channels 107 of each stack 133.

In FIG. 1G, sacrificial dielectric nanostructures 135 have been deposited in place of the sacrificial semiconductor nanostructures 109, in accordance with some embodiments. In particular, sacrificial dielectric nanostructures 135 have been deposited between the channels 107 of each stack 133. The sacrificial dielectric nanostructures 135 can be formed by conformally depositing a dielectric material in the source/drain trenches 131. The dielectric material fills the gaps between the channels 107. A subsequent anisotropic etching process can be performed to remove the dielectric material from all locations outside the coverage of the sacrificial gate structures 115. In some embodiments, the sacrificial dielectric nanostructures 135 includes silicon oxide. Alternatively, the sacrificial dielectric nanostructures 135 can include SiON, SiN, SiC, SiOC, SiOCN, or other suitable dielectric materials. The dielectric material can be deposited by CVD, ALD, or other suitable deposition processes. The sacrificial dielectric nanostructures 135 are one example of sacrificial nanostructures. In some embodiments, the sacrificial dielectric nanostructures are disposable oxide interposers (DOI).

FIG. 1H is a cross-sectional view of the integrated circuit 100 of FIG. 1G, taken along cut lines 1H, in accordance with some embodiments. The view of FIG. 1H illustrates the sacrificial dielectric nanostructures 135 between the channels 107 of each stack 133.

In FIG. 1I, a selective etching process is performed to recess exposed end portions of the sacrificial dielectric nanostructures 135 without substantially etching the channels 107, in accordance with some embodiments. The material of the sacrificial dielectric nanostructures 135 is selectively etchable with respect to the material of the semiconductor channels 107. Accordingly, the sacrificial dielectric nanostructures 135 can be recessed without substantially etching the channels 107.

FIG. 1J is a cross-sectional view of the integrated circuit 100 of FIG. 1I taken along cut lines 1J, in accordance with some embodiments. The view of FIG. 1J illustrates recesses 137 formed between channels 107 of each stack 133 by etching the sacrificial dielectric nanostructures 135 as described in FIG. 1I.

In FIG. 1K, an inner spacer liner layer 139 has been conformally deposited on all exposed surfaces, in accordance with some embodiments. The inner spacer liner layer 139 can include a dielectric material such as SiCN, SiOCN, or the like, formed by a suitable deposition method such as physical vapor deposition (PVD), CVD, ALD, or the like. Notably, the inner spacer liner layer 139 lines the interior of the recesses 137. The inner spacer liner layer 139 may have a thickness between 0.5 nm and 3 nm, though other thicknesses can be utilized without departing from the scope of the present disclosure.

FIG. 1L is a cross-sectional view of the integrated circuit 100 of FIG. 1K taken along cut lines 1L, in accordance with some embodiments. FIG. 1 illustrates how the thin inner spacer liner layer 139 is deposited on the interior surfaces of the recesses 137. In particular, the thin inner spacer liner layer 139 is deposited on the exposed top, bottom, and side surfaces of the channels 107. The inner spacer liner layer 139 is also formed on exposed sidewalls of the sacrificial dielectric nanostructures 135.

In FIG. 1M, a dielectric material 141 has been deposited in the recesses 137, filling the recesses, in accordance with some embodiments. In one embodiment, the dielectric material 141 includes silicon oxide. Alternatively, the dielectric material can include SiON, SiN, SiC, SiOC, SiOCN or other suitable dielectric materials. The dielectric material 141 can be deposited by CVD, ALD, or other suitable deposition processes. Initially, the dielectric material 141 may be deposited on all exposed surfaces. After deposition, an anisotropic etching process that etches selectively in the vertical direction is performed to remove the dielectric material 141 from all locations except within the recesses 137. The dielectric material 141 is selectively etchable with respect to the inner spacer liner layer 139.

In FIG. 1N, an etching process has been performed to remove the inner spacer liner layer 139 from all locations except within the recesses 137, in accordance with some embodiments. The etching process can include an anisotropic etching process that selectively etches in the downward direction so that all material of the inner spacer liner layer 139 is removed apart from within the recesses 137.

FIG. 1O is a cross-sectional view of the integrated circuit 100 of FIG. 1N taken along cut lines 1O, in accordance with some embodiments. FIG. 1O illustrates that the inner spacer liner layer 139 has been removed from all locations outside the recesses 137. A portion of the dielectric material 141 remains within the recesses in contact with the inner spacer liner layer 139.

In FIG. 1P, an etching process has been performed to remove the dielectric material 141 from the recesses 137, in accordance with some embodiments. Because the dielectric material 141 is selectively etchable with respect to the material of the inner spacer liner layer 139, the dielectric material 141 can be removed without substantially etching the inner spacer liner layer 139. The result is a gap or void in the recesses 137. The dielectric material 141 is removed as part of a pre-cleaning process prior to and in preparation for an epitaxial growth process for source/drain regions. The precleaning process can include one or more etching processes.

In FIG. 1Q source/drain regions 143 have been formed in the source/drain trenches 131, in accordance with some embodiments. In the illustrated embodiment, the source/drain regions 143 are epitaxially grown from epitaxial material(s). The source/drain regions 143 are grown on exposed portions of the channels 107 and the substrate 102 in the trenches 131.

For each stack 133, there are two source/drain regions 143, though only a single source/drain region 143 is shown for each stack 133 in FIG. 1Q due to the nature of the perspective view of FIG. 1Q. Each source/drain region 143 is in direct contact with the side surfaces of the channels 107 of the corresponding stack 133. The channels 107 of each stack 133 extend in the X-direction between two source/drain regions 143.

The dielectric support elements 127 that remain on the trench isolation regions 112 laterally confine the growth of source/drain regions 143 in the X-direction as they grow upward from the substrate 102 and the channels 107. In some embodiments, the source/drain regions 143 exert stress in the respective channels 107, thereby improving performance.

The source/drain regions 143 may include any acceptable material, such as appropriate for n-type or p-type devices. For n-type devices, the source/drain regions 143 include materials exerting a tensile strain in the channel regions, such as Si, SiC, SiCP, SiP, or the like, in some embodiments. When p-type devices are formed, the source/drain regions 143 include materials exerting a compressive strain in the channel regions, such as SiGe, SiGeB, Ge, GeSn, or the like, in accordance with certain embodiments. The source/drain regions 143 may have surfaces raised from respective surfaces of the fins and may have facets. Neighboring source/drain regions 143 may merge in some embodiments to form a singular source/drain region 143 over two neighboring fins of the fins 104.

The source/drain regions 143 may be implanted with dopants followed by an annealing process. The source/drain regions 143 may have an impurity concentration of between about 10¹⁹ cm⁻³ and about 10²¹ cm⁻³. N-type and/or p-type impurities for source/drain regions 143 may be any of the impurities previously discussed. In some embodiments, the source/drain regions 143 are in situ doped during growth.

In FIG. 1Q, a contact etch stop layer (CESL) 148 and an interlayer dielectric (ILD) 150 have been formed. The CESL layer 148 can include a thin dielectric layer can formally deposited on exposed surfaces of the source/drain regions 143, the dielectric support elements 127, and the trench isolation regions 112. The CESL layer 148 can include SiN, SiC, SiOC, SiOCN, SiON, or other suitable dielectric materials. The CESL 148 can be deposited by CVD, ALD, PVD, or other suitable deposition processes.

The dielectric layer 150 covers the CESL 148. The dielectric layer 150 can include SiO, SiON, SiN, SiC, SiOC, SiOCN or other suitable dielectric materials. The dielectric layer 150 can be deposited by CVD, ALD, PVD, or other suitable deposition processes.

FIG. 1R is a cross-sectional view of the integrated circuit 100 of FIG. 1Q, taken on cut lines 1R, in accordance with some embodiments. FIG. 1R illustrates that the source/drain regions 143 have been formed in the trenches 131. FIG. 1R illustrates how each channel 107 of a stack 133 extends in the X direction between two source/drain regions 143. FIG. 1R illustrates the ESCL layer 148 and the interlevel dielectric layer 150 above the source/drain regions 143 and between the sacrificial gate structures 115.

Inner spacers 146 are also positioned between the sacrificial dielectric nanostructures 135 and the source/drain regions 143. Each inner spacer 146 corresponds to the inner spacer liner layer 139 and a void or gap 147. The gap 147 may be filled with air or may be substantially at vacuum. The gaps 147 result from the presence of the unfilled the recesses 137 and the epitaxial growth of the source/drain regions 143. In particular, the source/drain regions 143 grown epitaxially from the semiconductor material of the channels 107 and the substrate 102. However, the source/drain regions 143 do not grow from the inner spacer liner layer 139. Accordingly, if the epitaxial growth process is carefully timed, then the source/drain regions 143 will form as shown in FIG. 1R with gaps 147. The gaps 147 can include a gas such as air or another inert gas. The gaps 147 can also be substantially at vacuum.

In FIG. 1R, the source/drain regions 143 have concave or otherwise curved surfaces at the boundaries with the gaps 147. This corresponds to the gaps 147 protruding into the source/drain regions 143. Alternatively, the source/drain regions 143 may have substantially flat sidewalls of the boundary with the gaps 147. The curved shape of the source/drain regions 143 at the boundaries with the gaps 147 can result from the nature of the epitaxial growth process of the source/drain regions 143. The source/drain regions 143 are grown epitaxially from the semiconductor material of the channels 107. However, the source/drain regions 143 do not grow from the dielectric material of the inner spacer liner layer 139. This growth can result in the curved surfaces shown in FIG. 1R. However, the surfaces of the source drain regions 143 can have other shapes at the boundaries with the gaps 147 without departing from the scope of the present disclosure.

The inner spacers 146 act as electrical insulation between source/drain regions 143 and gate metals that will be formed in place of the sacrificial dielectric nanostructures 135, as will be described in more detail below. Due to the very low dielectric constant of air, other inert gases, or vacuum, the presence of the gaps 147 in the inner spacers 146 results in a very low capacitance between the source/drain regions 143 and the gate metals that will subsequently be formed. This can result in greatly improved electrical characteristics of individual transistors and electronic circuits formed of the transistors.

FIG. 1S is an enlarged cross-sectional view of an individual inner spacer 146, in accordance with some embodiments. The view of FIG. 1S illustrates a source/drain region 143 abutting two stacked channels 107. A dielectric nanostructure 135 is positioned between the two stacked channels 107. The inner spacer 146 includes an inner spacer liner layer 139 in contact with the sidewalls of the dielectric nanostructure 135 and the exposed surfaces of the channels 107.

A dimension D1 corresponds to a distance between the inner spacer liner layer 139 and the most inward point of the concave surface of the source/drain region 143. The dimension D1 corresponds to the width of the gap 147 and can be between 3 nm and 15 nm, though other dimensions can be utilized without departing from the scope of the present disclosure. A dimension D2 corresponds to the width of the portion of the gap 147 that is external to the recess 137. The dimension D2 may be between 1 nm and 10 nm. The dimension D3 corresponds to the height of the gap 147 and may be between 3 nm and 15 nm. The dimension D4 corresponds to the inner height of the gap 147 and may have a value between 1 nm and 10 nm. The inner spacer liner layer can have a thickness between 0.5 nm and 3 nm. Other dimensions can be utilized for the inner spacer 146 without departing from the scope of the present disclosure. If the gap 147 is too wide, the precursor of the source/drain epitaxial growth may not be enough in there may be a defect in the source/drain region 143. If the gap 147 is too narrow in terms of height or width, then the capacitance between the source/drain region and a subsequently formed gate metal may be undesirably high. If the thickness of the inner spacer liner layer 139 is too great, then the gap 147 may be undesirably small, resulting in undesirably high capacitances or the gap may be entirely consumed during the process for releasing the channels 107.

As can be seen in FIG. 1S, the ends of the inner spacer liner layer 139 may also be curved. This can result from the etching process utilized to remove the dielectric material 141 as described in relation to FIG. 1P. While the dielectric material 141 is selectively etchable with respect to the material of the inner spacer liner layer 139, a small amount of etching may nevertheless occur at the inner spacer liner layer 139, possible resulting in curved ends.

FIG. 1T is a perspective view taken along cut lines 1T from FIG. 1Q, in accordance with some embodiments. The cut line goes through the sacrificial gate structure 115 in the Y direction. This view illustrates the presence of the channels 107 and sacrificial dielectric nanostructures 135 of each stack 133. This view also illustrates the interlevel dielectric layer 150 separated from the layer 119 by the gate spacer layer 125.

FIG. 1U is a perspective view from a same cut line as FIG. 1T, in accordance with some embodiments. In FIG. 1U, the sacrificial gate structure 115 has been removed. The layers 117, 119, 121, and 123 of the sacrificial gate structure have all been removed. The result is that there is a gap between the gate spacers 125 (only a single gate spacer 125 is apparent in FIG. 1U). The gap exposes the channels 107 and the sacrificial dielectric nanostructures 135 of each stack 133.

Removal of the sacrificial gate structures 115 can include first performing a planarization process, such as a CMP to level the top surfaces of the sacrificial gate layer 119 and gate spacer layer 125. The planarization process may also remove the dielectric layers 121 and 123 on the sacrificial gate layer 119, and portions of the gate spacer layer 125 along sidewalls of the dielectric layers 121 and 123. Accordingly, the top surfaces of the sacrificial gate layer 119 are exposed.

Next, the sacrificial gate layer 119 can be removed in an etching process, so that recesses are formed. In some embodiments, the sacrificial gate layer 119 is removed by an anisotropic dry etch process. For example, the etching process may include a dry etch process using reaction gases that selectively etch the sacrificial gate layer 119 without etching the spacer layer 125. The sacrificial gate dielectric layer 117, when present, may be used as an etch stop layer when the sacrificial gate layer 119 is etched. The sacrificial gate dielectric layer 117 may then be removed after the removal of the sacrificial gate layer 119.

FIG. 1V is a perspective view from a same cut line as FIG. 1U, in accordance with some embodiments. In FIG. 1V, an etching process has been performed to entirely remove the sacrificial dielectric nanostructures 135 from each stack 133. This corresponds to releasing the channels 107. Because the sacrificial dielectric nanostructures 135 are selectively etchable with respect to the channels 107, the channels 107 are not substantially etched during removal of the sacrificial dielectric nanostructures 135. The result is that there is a gap 151 between each of the channels 107 in each stack 133. The inner spacer liner layer 139 is apparent between the channels 107.

The sacrificial dielectric nanostructures 135 can be removed by a selective etching process using an etchant that is selective to the material of the sacrificial dielectric nanostructures 135, such that the sacrificial dielectric nanostructures 135 are removed without substantially etching the channels 107. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial dielectric nanostructures 135 are removed and the channels 107 are patterned to form channel regions of both PFETs and NFETs.

In some embodiments, the channels 107 are reshaped (e.g. thinned) by a further etching process to improve gate fill window. The reshaping may be performed by an isotropic etching process selective to the channels 107. After reshaping, the channels 107 may exhibit the dog bone shape in which middle portions of the channels 107 are thinner than peripheral portions of the channels 107 along the X-axis direction.

FIG. 1W is an enlarged cross-sectional view as in FIG. 1S, but at the stage of processing shown in FIG. 1V, in accordance with some embodiments. In particular, the dielectric nanostructure 135 has been removed, leaving a gap 151 between the channels 106. The inner spacer liner layer 139 is between the gap 151 and the gap 147 of the inner spacer 146.

FIG. 1X is a perspective view of the integrated circuit 100 taken from a same cut line as FIG. 1V, in accordance with some embodiments. In FIG. 1X, an interfacial gate dielectric layer 155 has been deposited. The interfacial gate dielectric layer 155 is deposited on all exposed surfaces of the channels 107. The interfacial gate dielectric layer 155 surrounds the channels 107. The interfacial gate dielectric layer 155 can include a dielectric material such as silicon oxide, silicon nitride, or other suitable dielectric materials. The interfacial gate dielectric layer 155 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 155 can be formed by a thermal oxidation process, a chemical vapor deposition (CVD) process, or an atomic layer deposition (ALD) process. The interfacial gate dielectric layer 155 can have a thickness between 0.5 nm and 2 nm. Other materials, deposition processes, and thicknesses can be utilized for the interfacial gate dielectric layer 155 without departing from the scope of the present disclosure.

In FIG. 1X, a high-K dielectric layer 157 has been deposited. The high-K dielectric layer 157 is deposited in a conformal deposition process. The conformal deposition process deposits the high-K dielectric layer 157 on the interfacial gate dielectric layer 155 and on sidewalls of the gate spacer layers 125. The high-K gate dielectric layer 157 surrounds the channels 107. The high-K gate dielectric layer 157 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 157 may be formed by CVD, ALD, or any suitable method. Other thicknesses, deposition processes, and materials can be utilized for the high-K dielectric layer 157 without departing from the scope of the present disclosure.

In FIG. 1X, a gate metal 159 has been deposited. The gate metal 159 is deposited on all exposed surfaces of the high-K dielectric layer 157. The gate metal 159 substantially surrounds channels 107. Although the gate metal 159 is shown as a single layer in FIG. 1X, in practice, the gate metal 159 can include one or more conductive liner layers, work function layers, and gate fill layers that collectively make up the gate metal 159. The gate metal 159 can include one or more of Ti, TiN, Ta, TaN, Al, Cu, Co, Ru, W, Au, or other suitable conductive materials. The gate metal 159 can be deposited by PVD, ALD, or CVD. Other configurations, materials, and deposition processes can be utilized for the gate metal 159 without departing from the scope of the present disclosure.

At the stage of processing shown in FIG. 1X, transistors 103 are substantially complete. FIG. 1X shows portions of three transistors 103a, 103b, and 103c. The transistor 103a includes channels 107a extending between the source/drain regions 143a and acting as stacked channels of the transistor 103a. The gate metal 159 acts as a gate electrode surrounding the channels 107a. The transistor 103b includes channels 107b extending between the source/drain regions 143b and acting as stacked channels of the transistor 103b. The gate metal 159 acts as a gate electrode surrounding the channels 107b. The transistor 103c includes channels 107c extending between the source/drain regions 143c and acting as stacked channels of the transistor 103c. The gate metal 159 acts as a gate electrode surrounding the channels 107c. Only one each of the source/drain regions 143a-c are apparent in the view of FIG. 1X.

In FIG. 1X, there are no breaks in the gate metal 159, such that the gate electrodes of the transistors 103 are all shorted together. Though not shown in FIG. 1X, in further processing steps etching processes may be performed to electrically isolate portions of the gate metal 159 to form electrically isolated gate electrodes for the transistors 103. These processes may be termed “cut metal gate” (CMG) processes.

FIG. 1Y is a perspective view of the integrated circuit 100 at the stage of processing of FIG. 1X, but with a cut line shifted in the X direction such that the cut line is taken to the source/drain regions 143a-c, in accordance with some embodiments. Another cut has been made to reveal an inner portion of the transistor 103c. In particular, the cut illustrates the position of the source/drain region 143c relative to the gaps 147 of the inner spacers 146 between the channels 107c.

FIG. 1Z is a cross-sectional view of the integrated circuit 100 at the stage of processing of FIG. 1Y, taken along cut lines 1Z from FIG. 1Y, in accordance with some embodiments. The view of FIG. 1Z illustrates the transistor 103b. In particular, the channels 107b extend in the X direction between source/drain regions 143b. The interfacial gate dielectric layer 155 is positioned on the surfaces of the channels 107b. The high-K gate dielectric layer 157 is positioned on the interfacial dielectric layer 155 and on the inner spacer liner layer 139. The gate metal 159 is positioned around the channels 107b and is separated from the channels 107b by the interfacial gate dielectric layer 155 and the high-K gate dielectric layer 157. A trench fill portion of the gate metal 159 is positioned above the stacked channels 107b between the gate spacers 125.

FIG. 1Z illustrates the inner spacers 146 that electrically isolate the source/drain regions 143b from the gate metal 159. Each inner spacer 146 includes the inner spacer liner layer 139 and the gap 147. The gaps 147 have a shape previously described, the source/drain regions 143b have the concave shape at the interface with the gaps 147, as previously described.

Though not shown in FIG. 1Z, metal source/drain contacts may be formed to electrically connect to the source/drain regions 143. Conductive vias may be formed to electrically connect to the metal source/drain contacts.

FIG. 2 is an enlarged cross-sectional view of a portion of the transistor 103b, in accordance with some embodiments. The enlarged cross-sectional view of FIG. 2 is a same view as the enlarged cross-sectional view of FIG. 1X, but at the stage of processing of FIG. 1Z. FIG. 2 illustrates an inner spacer 146 electrically isolating the gate metal 159 of the transistor 103b from the source/drain region 143b. The inner spacer 146 includes the inner spacer liner layer 139 and the gap 147. The inner spacer 146 has a dimensions D1-D4 as described previously in relation to FIG. 1S. FIG. 2 also illustrates the curved ends 161 of the inner spacer liner layer 139.

The inner spacers 146 act as electrical insulation between source/drain region 143b and gate metal 159 that has been formed in the place of the previously removed sacrificial dielectric nanostructures 135. Due to the very low dielectric constant of air, the presence of the gaps 147 in the inner spacers 146 results in a very low capacitance between the source/drain regions 143 and the gate metal 159. This can result in greatly improved electrical characteristics of individual transistors and electronic circuits formed of the transistors.

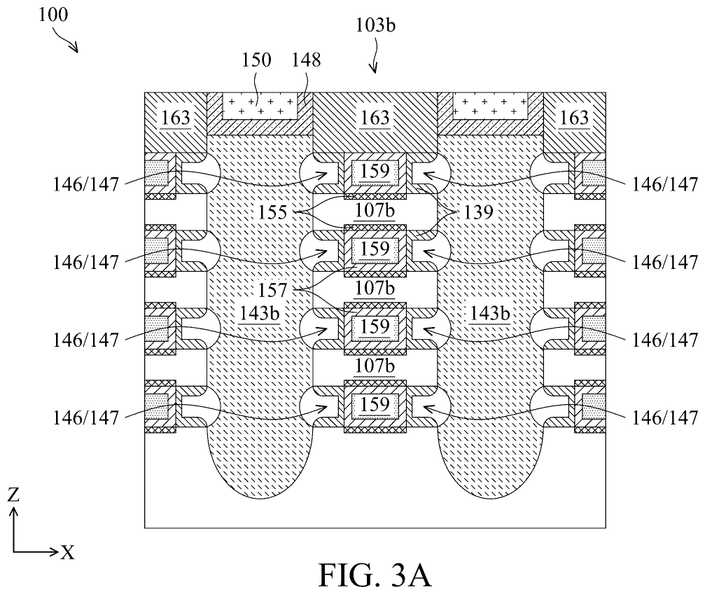

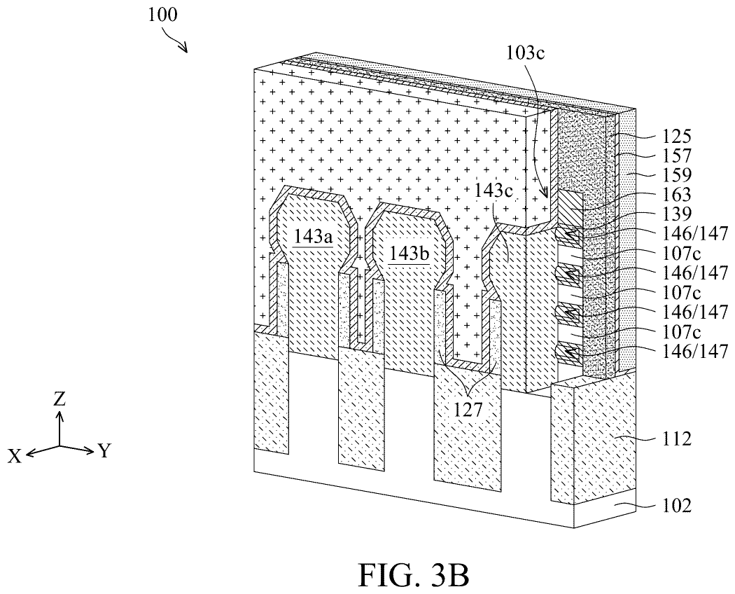

FIG. 3A is a cross-sectional view of an integrated circuit 100, in accordance with some embodiments. The integrated circuit 100 of FIG. 3A is at the stage of processing shown in FIG. 1Z. However, the integrated circuit 100 of FIG. 3A includes a dielectric structure 163 above the stacked channels 107b of the transistor 103b. All of the transistors 103 can have the dielectric structure 163. The dielectric structure 163 may also be termed a dielectric helmet structure.

In FIG. 3A, there are three stacked channels 107b. However, rather than the gate fill portion of the gate metal 159 directly above the highest stacked channel 107b, there is an additional gate metal structure and inner spacer 146. In this case, there are four inner spacers 146 on each side of the stacked channels 107b rather than the three inner spacers 146 of FIG. 1z.

The dielectric structure 163 is positioned between the top channel 107b and the upper trench fill portion of the gate metal 159. This results in a further reduction in the capacitance between the source/drain regions 143b and the gate metal 159. Though not apparent in the view of FIG. 3A, the upper trench fill portion of the gate metal 159 and the gate spacers 125 are positioned on top of the dielectric structure 163. The high-K gate dielectric layer 157 may be positioned on top of the dielectric structure 163.

Formation of the dielectric structure 163 may begin when the initial stack of semiconductor layers 106 and sacrificial semiconductor layers 108 is formed, prior to definition of the fins 104. In particular, whereas a top layer of the initial stack of FIG. 1A is a semiconductor layer 106, in embodiments in which a structure 163 is to be formed, an additional sacrificial semiconductor layer 108 is positioned on the top semiconductor layer 106. A sacrificial semiconductor layer is positioned on top of the top sacrificial semiconductor layer 108. In an example in which the semiconductor layers 106 are silicon and the sacrificial semiconductor layers 108 are silicon germanium, the sacrificial semiconductor layer can include silicon germanium having a different concentration of germanium than the sacrificial semiconductor layers 108. In some embodiments, the sacrificial semiconductor layers 108 have a germanium concentration between 15% and 30%. The sacrificial semiconductor layer has a concentration that is at least 15% higher than the germanium concentration of the sacrificial semiconductor layers 108. This enables the sacrificial semiconductor layers 108 to be selectively etched with respect to the sacrificial semiconductor layer.

After the stack is patterned to form the fins 104, each fin 104 includes the additional sacrificial semiconductor layer 108 above the top semiconductor layer 106. Each fin 104 also includes the sacrificial semiconductor layer on the top sacrificial semiconductor layer 108. At the stage of processing shown in FIG. 1D, after formation of the source/drain trenches, an etching process can be performed that selectively etches the sacrificial semiconductor layer with respect to the sacrificial semiconductor layers 108 and the semiconductor layers 106. The dielectric structures 163 can then be deposited in place of the sacrificial semiconductor layer of each fin 104 or stack 133. The dielectric structure 163 is of a dielectric material that is selectively etchable with respect to the sacrificial dielectric nanostructures 135. Accordingly, when the sacrificial dielectric nanostructures 135 are subsequently removed, the dielectric structure 163 remains. The gate dielectric layers 155/157 and the gate metal 159 are then deposited on and around the dielectric structure 163 of each transistor 103. Accordingly, the gate metal 159 may include a portion above the dielectric structure. As shown in FIG. 3A, a top surface of the source/drain regions 143b is higher than a bottom surface of the dielectric structures 163.

The dielectric structures 163 can include a dielectric material such as SiN, SiCN, SiOCN, SiOC, or other suitable materials. The dielectric structures 163 can be formed by CVD, ALD, PVD, or other suitable deposition processes. The dielectric structure 163 can have a height in the Z direction between 3 nm and 15 nm. If the height of the dielectric structure 163 is too high, then an aspect ratio of the source/drain regions 143 may be undesirably high and processing the source/drain regions 143 may be difficult. If the height of the dielectric structure 163 is too small, then the dielectric structure 163 may be consumed in a subsequent CMP process. The presence of dielectric structures 163 greatly reduce the capacitance between the gate metal 159 and the source/drain regions 143 of each transistor 103, as set forth previously.

FIG. 3B is a perspective view of the integrated circuit 100 of FIG. 3A, taken along a similar view as FIG. 1Y, in accordance with some embodiments. The cutaway portion illustrates an inner portion of the transistor 103c including the dielectric structure 163 on top of the uppermost inner spacer liner layer 139.

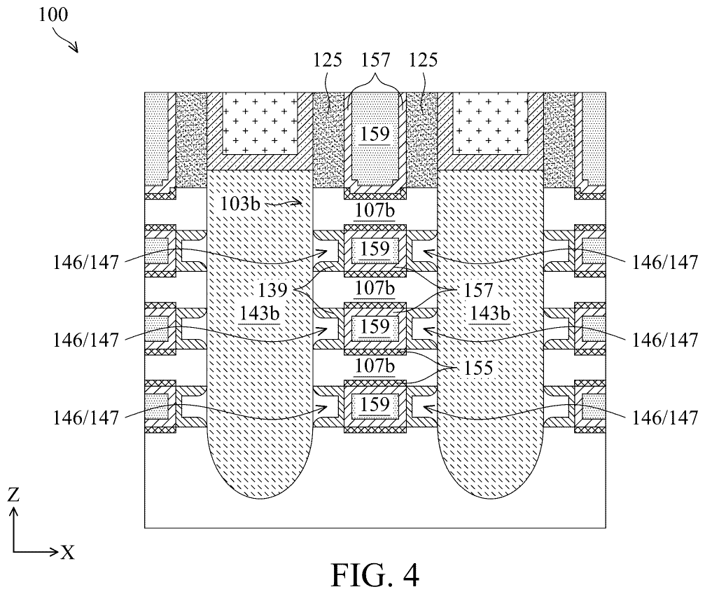

FIG. 4 is a cross-sectional view of an integrated circuit 100, in accordance with some embodiments. The integrated circuit 100 of FIG. 4 is of a same view and a same stage of processing as the integrated circuit 100 of FIG. 1Z. However, in FIG. 4, the sidewalls of the source/drain regions 143b are straight at the boundary of the gaps 147 of the inner spacers 146.

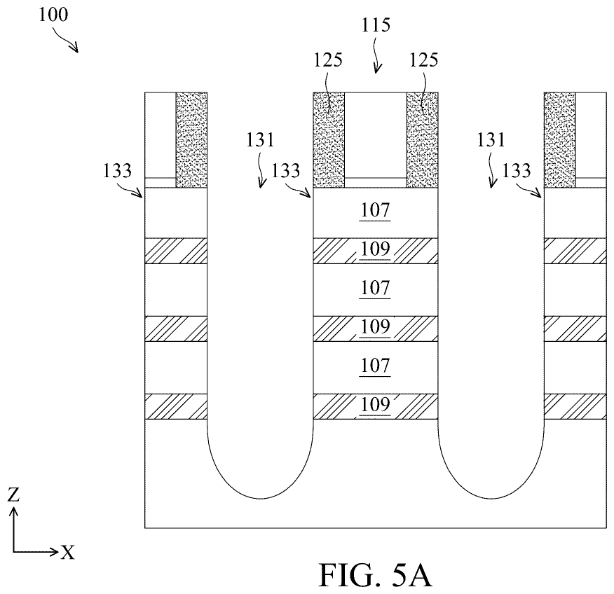

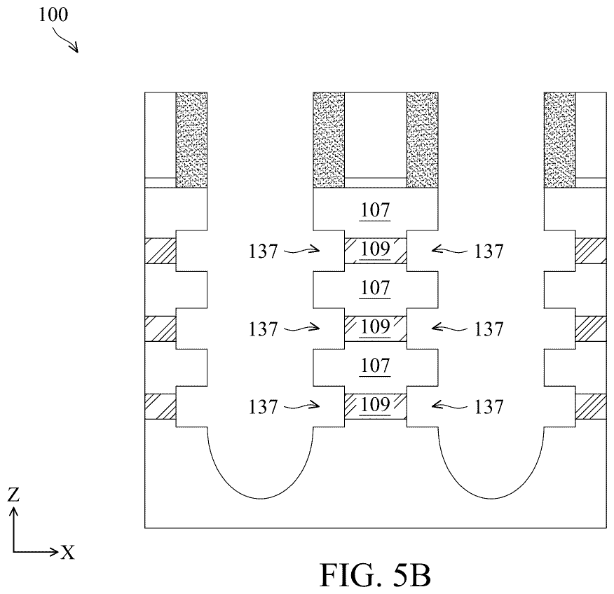

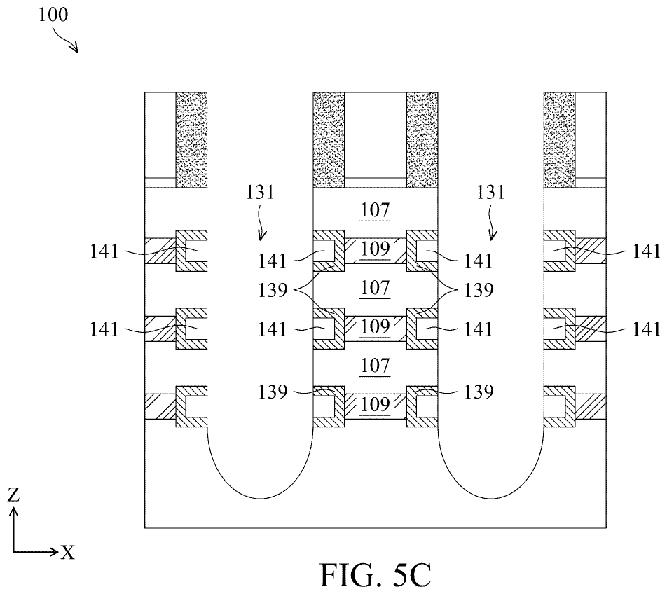

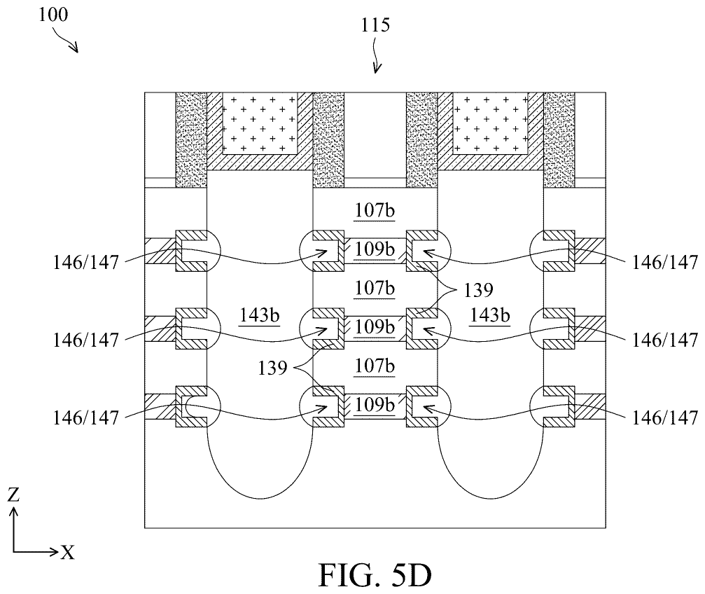

FIGS. 5A-5D are cross-sectional views of an integrated circuit 100 at various stages of processing, in accordance with some embodiments. In FIG. 5A, the integrated circuit 100 is at a same stage of processing as shown in FIG. 1E.

In FIG. 5B, recesses 137 have been formed between the channels 107 by partially etching the sacrificial semiconductor nanostructures 109, in accordance with some embodiments. In particular, an etching process as described in relation to FIGS. 11 and 1J has been performed, except that the sacrificial semiconductor nanostructures 109 have been selectively etched instead of the sacrificial dielectric nanostructures 135. Accordingly, in FIGS. 5A-5D, the sacrificial semiconductor nanostructures 109 are never replaced with the sacrificial dielectric nanostructures 135 as described in relation to FIGS. 1F-1H. Accordingly, the recessing step described in relation to FIGS. 11 and 1J is performed on the sacrificial semiconductor nanostructures 109 rather than on the sacrificial dielectric nanostructures 135. The sacrificial semiconductor nanostructures 109 are selectively recessed with respect to the channels 107.

In FIG. 5C, the integrated circuit 100 is at the stage of processing shown in FIG. 1O, except that the sacrificial semiconductor nanostructures 109 are present rather than the sacrificial dielectric nanostructures 135, in accordance with some embodiments. In particular, the inner spacer liner layers 139 have been formed in contact with the sacrificial semiconductor nanostructures 109. The dielectric material 141 has also been formed. Formation of the inner spacer liner layers 139 and the dielectric material 141 can occur substantially as described in relation to FIGS. 1K-1O.

In FIG. 5D, the integrated circuit 100 is at the stage of processing shown in FIG. 1R, in accordance with some embodiments. The integrated circuit 100 of FIG. 5D differs from the integrated circuit 100 of FIG. 1R in that the sacrificial semiconductor nanostructures 109b are present rather than the sacrificial dielectric nanostructures 135. The inner spacers 146, including the gaps 147 and the inner spacer liner layers 139, are present substantially as described in relation to FIG. 1R.

Subsequently, processing steps can be performed substantially as described in FIGS. 1U-1Z in order to achieve substantially the same structure as shown in FIG. 1Z. The difference is that the sacrificial semiconductor nanostructures 109b are removed, rather than the sacrificial dielectric nanostructures 135, to release the channels 107 prior to formation of the interfacial dielectric layer 155, the high-K gate dielectric layer 157, and the gate metal 159.

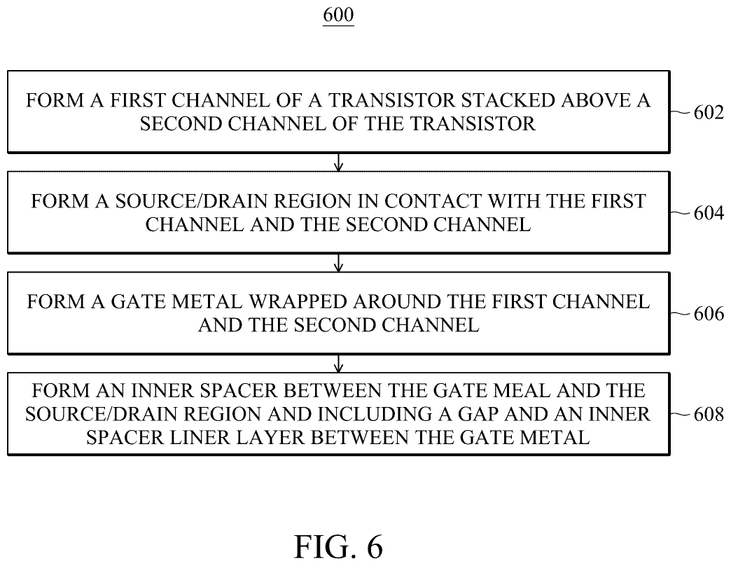

FIG. 6 is a flow diagram of a method 600 for forming an integrated circuit, in accordance with some embodiments. The method 600 can utilize the structures, processes, and systems described in relation to FIGS. 1A-5D. At 602, the method 600 includes forming a first channel of a transistor stacked above a second channel of the transistor. One example of a transistor is the transistor 103b of FIG. 1Z. One example of a first channel is the highest channel 107b of FIG. 1Z. One example of a second channel is the second highest channel 107b of FIG. 1Z. At 604, the method 600 includes forming a source/drain region in contact with the first channel and the second channel. One example of a source/drain region is the source/drain region 143b of FIG. 1Z. At 606, the method 600 includes forming a gate metal wrapped around the first channel and the second channel. One example of a gate metal is the gate metal 159 of FIG. 1Z. At 608, the method 600 includes forming an inner spacer between the gate metal and the source/drain region and including a gap and an inner spacer liner layer between the gate metal. One example of an inner spacer is the inner spacer 146 of FIG. 1Z. One example of a gap is the gap 147 of FIG. 1Z. One example of an inner spacer liner layer is the inner spacer liner layer 139 of FIG. 1Z.

Embodiments of the disclosure reduce the capacitance between the source/drain regions and gate metals of a nanostructure transistor. The nanostructure transistor includes a plurality of channel regions extending between adjacent source/drain regions. The gate metal surrounds a portion of the channel regions. Inner spacers are formed between the source/drain regions and gate metal to electrically isolate the source/drain regions from the gate metal. Embodiments of the present disclosure form the inner spacers with a thin inner spacer liner layer between the gate metal and the source/drain regions. The inner spacers also include a gap or void between the inner spacer liner layer and the source/drain regions. The gaps have a very small dielectric constant. This results in a very low gate to source/drain capacitance. The low gate to source/drain capacitance results in improved performance of the transistor and improve performance of circuits implementing the transistor. This results in improved wafer yields and better functioning electronic devices.

In one embodiment, a device includes a transistor. The transistor includes a plurality of stacked channels, a source/drain region coupled to the stacked channels, and a gate metal wrapped around the stacked channels. The transistor includes a plurality of inner spacers, each inner spacer being positioned laterally between the gate metal and the source/drain region and including a gap between the gate metal and the source/drain region.

In one embodiment, a method includes forming a first channel of a transistor stacked above a second channel of the transistor and forming a source/drain region in contact with the first channel and the second channel. The method includes forming a gate metal wrapped around the first channel and the second channel and forming an inner spacer between the gate metal and the source/drain region and including a gap and an inner spacer liner layer between the gate metal.

In one embodiment, a device includes a transistor. The transistor includes a plurality of stacked channels, a source/drain region in contact with each of the stacked channels, and a gate metal wrapped around the stacked channels and including an upper portion above a highest channel of the stacked channels. The transistor includes an inner spacer including a gap above the highest channel and laterally between the upper portion of the gate metal and the source/drain region and a dielectric structure above the gap and in contact with the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a transistor including:
a first channel;
a second channel above the first channel;
a source/drain region coupled to the first and second channels;
a gate metal wrapped around the first channel and the second channel;
a gate dielectric layer on a sidewall of the gate metal between the first channel and the second channel and between the gate metal and the source/drain region;
a dielectric liner layer on a top surface of the first channel, a bottom surface of the top channel, and a side surface of the gate dielectric layer between the gate metal and the source/drain region.

2. The device of claim 1, wherein the transistor includes a gap between the dielectric liner layer and the source/drain region.

3. The device of claim 1, wherein the gap protrudes into the source/drain region.

4. The device of claim 2, wherein the source/drain has region has a sidewall that is concave where the sidewall abuts the gap of each inner spacer.

5. The device of claim 2, comprising:
a source/drain contact electrically connected to the source/drain region;
a gate spacer between the source/drain contact and the gate metal; and
a dielectric structure above the highest channel, wherein a portion of the gate metal is above the dielectric structure, wherein a top of the gate spacer is higher than a top of the dielectric structure.

6. The device of claim 5, wherein a bottom surface of the dielectric structure is lower than a top surface of the source/drain region.

7. The device of claim 5, wherein the dielectric structure is in contact with the source/drain region and a gate dielectric layer above the highest channel.

8. The device of claim 1, wherein the dielectric liner layer has a curved end adjacent to the source/drain region.

9. The device of claim 8, wherein the dielectric liner layer has a thickness between 0.5 nm and 3 nm.

10. The device of claim 1, wherein source/drain region has a straight sidewall abutting each of the gaps.

11. A method, comprising:
forming a first channel of a transistor stacked above a second channel of the transistor;
forming a gate dielectric layer wrapped around the first channel and the second channel;
forming a source/drain region in contact with the first channel and the second channel;
forming a gate metal wrapped around the first channel and the second channel, wherein the gate dielectric layer includes a portion on a sidewall of the gate metal between the first and the second channel and between the gate metal and the source/drain region; and
forming a dielectric liner layer on a top surface of the first channel, a bottom surface of the top channel, and a side surface of the portion of the gate dielectric layer between the gate metal and the source/drain region and having a C-shape.

12. The method of claim 11, further comprising:
forming a sacrificial nanostructure between the first channel and the second channel prior to forming the gate metal;
forming a recess between the first channel and the second channel by laterally recessing the sacrificial nanostructure with respect to the first channel and the second channel; and
depositing the dielectric liner layer in the recess on a bottom of the first channel, on a top of the second channel, and on a lateral end of the sacrificial nanostructure.

13. The method of claim 12, wherein forming the inner spacer includes:
filling the recess by depositing a dielectric material on the inner spacer liner layer; and
removing the dielectric material.

14. The method of claim 13, comprising forming a gap between the dielectric liner layer and the source/drain region by epitaxially growing the source/drain region from the first channel and the second channel in the presence of the dielectric liner layer after removing the dielectric material.

15. The method of claim 14, wherein the source/drain region has a concave sidewall abutting the gap.

16. The method of claim 12, wherein forming the gate metal includes:
removing the sacrificial nanostructure; and
depositing the gate metal in place of the sacrificial nanostructure in a presence of the dielectric liner layer.

17. The method of claim 11, comprising forming a dielectric structure above the first channel and in contact with the source/drain region.

18. A method, comprising:
forming a plurality of stacked channels of a transistor;
forming a source/drain region in contact with each of the stacked channels;
forming a gate metal wrapped around the stacked channels and including an upper portion above a highest channel of the stacked channels;
forming an inner spacer including a dielectric liner layer above the highest channel and laterally between the upper portion of the gate metal and the source/drain region; and
forming a dielectric structure above the inner spacer and in contact with the source/drain region.

19. The method of claim 18, wherein the inner spacer includes a gap between the highest channel and the dielectric structure.

20. The method of claim 19, wherein the dielectric liner layer is exposed by the gap.
